(19) United States
(12) Patent Application Publication
(10) Pub. No.: US 2023/0337500 A1
(43) Pub. Date: Oct. 19, 2023

(54) COLOR CONVERTING PANEL AND DISPLAY DEVICE INCLUDING THE SAME

(71) Applicant: Samsung Display Co., LTD., Yongin-si (KR)

(72) Inventors: Ki Soo PARK, Yongin-si (KR); Yu Jin KIM, Yongin-si (KR); Hong Min YOON, Yongin-si (KR); Jun Han LEE, Yongin-si (KR)

(21) Appl. No.: 18/114,107

(22) Filed: Feb. 24, 2023

(30) Foreign Application Priority Data
Apr. 19, 2022 (KR) 10-2022-0048418

(51) Int. Cl. H10K 59/38; H10K 59/122; H10K 59/80

(52) U.S. Cl. CPC H10K 59/38; H10K 59/122; H10K 59/8792

(57) ABSTRACT

A color converting panel includes: a substrate; a plurality of banks disposed on the substrate, where the banks partition a red light emitting area, a green light emitting area, a blue light emitting area, and a white light emitting area; a red color conversion layer disposed in the red light emitting area; a green color conversion layer disposed in the green light emitting area; and a green color conversion layer and a red color conversion layer disposed in the white light emitting area.

This application claims priority to Korean Patent Application No. 10-2022-0048418, filed on Apr. 19, 2022, and all the benefits accruing therefrom under 35 U.S.C. § 119, the content of which in its entirety is herein incorporated by reference.

### BACKGROUND

### (a) Field

The disclosure relates to a color converting panel and a display device including the color converting panel.

### (b) Description of the Related Art

A light emitting element is an element in which holes supplied from an anode and electrons supplied from a cathode are combined in an organic emission layer to form excitons, and light is emitted while the excitons are stabilized, and a display device including the light emitting element has several desired characteristics such as a wide viewing angle, a fast response speed, a thin thickness, and lower power consumption such that the light emitting diode is widely applied to various electrical and electronic devices including a display device such as a television, a monitor, a mobile phone, etc.

Recently, to realize a display device with high efficiency, a display device including a color converting panel has been proposed. The color converting panel may convert incident light into different colors and transmit the converted light to an outside.

### SUMMARY

Embodiments of the invention has been made in an effort to provide a color converting panel with high efficiency and a display device including the color converting panel.

An embodiment of the invention provides a color converting panel including: a substrate; a plurality of banks disposed on the substrate, wherein the banks partition a red light emitting area, a green light emitting area, a blue light emitting area, and a white light emitting area; a red color conversion layer disposed in the red light emitting area; a green color conversion layer disposed in the green light emitting area; and a green color conversion layer and a red color conversion layer disposed in the white light emitting area.

In an embodiment, the green color conversion layer and the red color conversion layer in the white light emitting area may be stacked one on another.

In an embodiment, the green color conversion layer and the red color conversion layer may be mixed and disposed on one layer in the white light emitting area.

In an embodiment, the color converting panel may further include a transmission layer disposed in the blue light emitting area and the white light emitting area.

In an embodiment, the green color conversion layer, the red color conversion layer, and the transmission layer in the white light emitting area may be stacked one on another.

In an embodiment, the green color conversion layer, the red color conversion layer, and the transmission layer in the white light emitting area may be mixed with each other to define a single layer.

In an embodiment, the color converting panel may include a blue color conversion layer disposed in the blue light emitting area and the white light emitting area.

In an embodiment, the green color conversion layer, the red color conversion layer, and the blue color conversion layer in the white light emitting area may be stacked one on another.

In an embodiment, the green color conversion layer, the red color conversion layer, and the blue color conversion layer in the white light emitting area may be sequentially arranged in a direction perpendicular to a thickness direction of the substrate.

In an embodiment, the color converting panel may further include: a red color filter disposed on the substrate and overlapping the red light emitting area; a green color filter disposed on the substrate and overlapping the green light emitting area; and a blue color filter disposed on the substrate and overlapping the blue light emitting area.

In an embodiment, the color converting panel may further include a reflective color filter disposed on the substrate and overlapping the white light emitting area.

An embodiment of the invention provides a color converting panel including: a substrate; a plurality of banks disposed on the substrate, where the banks partition a red light emitting area, a green light emitting area, a blue light emitting area, and a white light emitting area; a red color conversion layer disposed in the red light emitting area; a green color conversion layer disposed in the green light emitting area; a blue color conversion layer disposed in the blue light emitting area; and a scatterer layer disposed in the white light emitting area, wherein the scatterer layer is disposed to overlap the red color conversion layer, the green color conversion layer, and the blue color conversion layer.

An embodiment of the invention provides a color converting panel including: a substrate; a plurality of banks disposed on the substrate, where the banks partition a red light emitting area, a green light emitting area, a blue light emitting area, and a white light emitting area; a red color conversion layer disposed in the red light emitting area; a green color conversion layer disposed in the green light emitting area; a blue color conversion layer disposed in the blue light emitting area; and a white color conversion layer disposed in the white light emitting area.

An embodiment of the invention provides a display device including: a color converting panel; and a display panel overlapping the color converting panel, wherein the display panel includes a second substrate, a plurality of partition walls disposed on the second substrate, and an emission layer disposed between the partition walls, and the color converting panel includes a first substrate, a plurality of banks disposed on the first substrate, where the banks partition a red light emitting area, a green light emitting area, a blue light emitting area, and a white light emitting area, a red color conversion layer disposed in the red light emitting area, a green color conversion layer disposed in the green light emitting area, and a green color conversion layer and a red color conversion layer disposed in the white light emitting area.

In an embodiment, the emission layer may include at least one emission layer, and the display panel may emit blue light or white light.

In an embodiment, the green color conversion layer and the red color conversion layer in the white light emitting area may be stacked one on another, or the green color conversion layer and the red color conversion layer in the white light emitting area may be mixed with each other to define a single layer.

In an embodiment, the display device may further include a transmission layer disposed in the blue light emitting area and the white light emitting area.

In an embodiment, the green color conversion layer, the red color conversion layer, and the transmission layer in the white light emitting area may be stacked one on another, or the green color conversion layer, the red color conversion layer, and the transmission layer in the white light emitting area may be mixed with each other to define a single layer.

In an embodiment, the display device may further include a blue color conversion layer disposed in the blue light emitting area and the white light emitting area.

In an embodiment, the green color conversion layer, the red color conversion layer, and the blue color conversion layer in the white light emitting area may be stacked one on another, or the green color conversion layer, the red color conversion layer, and the blue color conversion layer in the white light emitting area may be sequentially arranged in a direction perpendicular to a thickness direction of the first substrate.

According to embodiments, the color converting panel with high efficiency and the display device including the color converting panel are provided.

### BRIEF DESCRIPTION OF THE DRAWINGS

FIG. 1 shows a cross-sectional view of a color converting panel according to an embodiment.

FIG. 2 shows a cross-sectional view of an alternative embodiment of a color converting panel shown in FIG. 1.

FIG. 3 shows a cross-sectional view of another alternative embodiment of a color converting panel shown in FIG. 1.

FIG. 4 to FIG. 9 are enlarged views showing embodiments of with the circled portion B in FIG. 1.

FIG. 10 shows a cross-sectional view of another alternative embodiment of a color converting panel shown in FIG. 1 according to.

FIG. 11 shows a same cross-sectional view of another alternative embodiment of a color converting panel shown in FIG. 10.

FIG. 12 shows a same cross-sectional view of another alternative embodiment of a color converting panel shown in FIG. 10.

FIG. 13 shows a cross-sectional view of another alternative embodiment of a color converting panel shown in FIG. 10.

FIG. 14 shows a cross-sectional view of another alternative embodiment of a color converting panel shown in FIG. 10.

FIG. 15 shows a cross-sectional view of another alternative embodiment of a color converting panel shown in FIG. 10.

FIG. 16 shows a cross-sectional view of a display device according to an embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

Parts that are irrelevant to the description will be omitted to clearly describe embodiments of the invention, and the same elements will be designated by the same reference numerals throughout the specification.

The size and thickness of each configuration shown in the drawings are arbitrarily shown for better understanding and ease of description, but the invention is not limited thereto. In the drawings, the thickness of layers, films, panels, regions, etc., are enlarged for clarity. The thicknesses of some layers and areas are exaggerated for convenience of explanation.

It will be understood that when an element such as a layer, film, region, or substrate is referred to as being “on” another element, it can be directly on the other element or intervening elements may also be present. In contrast, when an element is referred to as being “directly on” another element, there are no intervening elements present. The word “on” or “above” means positioned on or below the object portion, and does not necessarily mean positioned on the upper side of the object portion based on a gravitational direction.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

The phrase “in a plan view” means viewing an object portion from the top, and the phrase “in a cross-sectional view” means viewing a cross-section of which the object portion is vertically cut from the side.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the claims.

Hereinafter, embodiments of the invention will now be described in detail with reference to accompanying drawings.

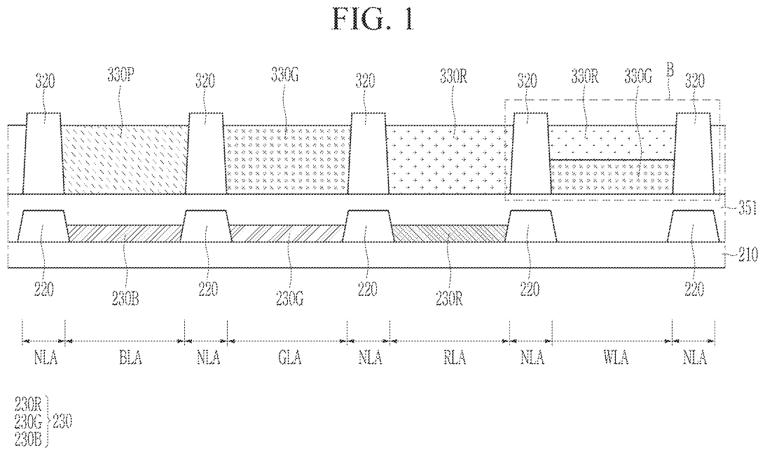

FIG. 1 shows a cross-sectional view of a color converting panel according to an embodiment. An embodiment of the color converting panel includes a bank 320 for partitioning respective light emitting areas, and a color conversion layer and a transmission layer positioned (disposed or arranged) in spaces partitioned by the bank 320. The color converting panel includes a red light emitting area RLA, a green light emitting area GLA, a blue light emitting area BLA, and a white light emitting area WLA.

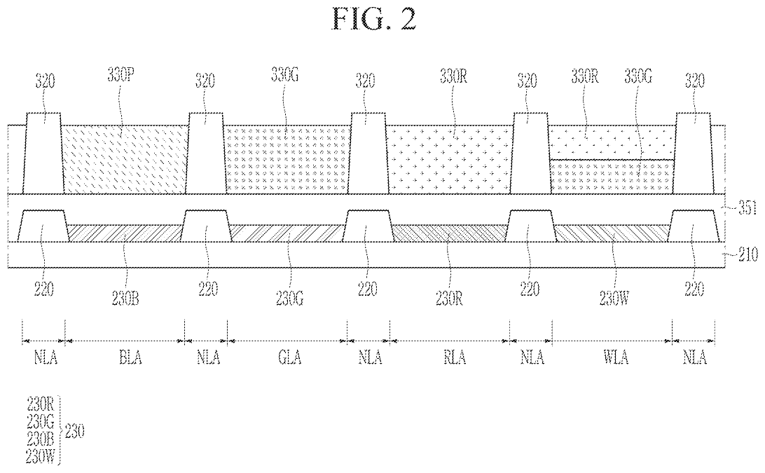

A color filter 230 including a blue color filter 230B, a red color filter 230R, and a green color filter 230G may be positioned on the first substrate 210. The respective color filters are positioned corresponding to respective light emitting areas. That is, the blue color filter 230B may be positioned in the blue light emitting area BLA, the red color filter 230R may be positioned in the red light emitting area RLA, and the green color filter 230G may be positioned in the green light emitting area GLA. A light blocking member 220 may be positioned between the respective color filters 230. The light blocking member 220 may be positioned in a non-light emitting area NLA. The color filter may not be positioned in the white light emitting area WLA. In an alternative embodiment, a color filter for reducing reflection may be positioned in the white light emitting area WLA. Such an embodiment will be described later with reference to FIG. 2.

Referring to FIG. 1, in an embodiment of the color converting panel, a low refractive layer 351 may be positioned on the color filter 230. A refractive index of the low refractive layer 351 may be equal to or less than about 1.2. The low refractive layer 351 may include a mixture of an organic material and an inorganic material.

A plurality of banks 320 may be positioned on the low refractive layer 351. The banks 320 may be spaced from each other with a plurality of openings therebetween, and areas between the bank 320 configure or define the red light emitting area RLA, the green light emitting area GLA, the blue light emitting area BLA, and the white light emitting area WLA.

The banks 320 may include scatterers. The scatterers may be at least one selected from SiO₂, BaSO₄, Al₂O₃, ZnO, ZrO₂, and TiO₂. The banks 320 may include a polymer resin and scatterers included in the polymer resin. A content of the scatterers may be in a range of about 0.1 weight percent (wt %) to about 20 wt %. In an embodiment, for example, the content of the scatterers may be in a range of about 5 wt % to about 10 wt %. The banks 320 including the scatterers in this range may scatter light emitted from the display panel and may increase light emitting efficiency. In an alternative embodiment, the banks 320 may include a black material to block light, and may prevent mixture of colors between the neighboring light emitting areas.

A red color conversion layer 330R may be positioned in the red light emitting area RLA. The red color conversion layer 330R may convert incident light into red light. The red color conversion layer 330R may include a quantum dot. A green color conversion layer 330G may be positioned in the green light emitting area GLA. The green color conversion layer 330G may convert incident light into green light. The green color conversion layer 330G may include a quantum dot.

The quantum dot will now be described in detail.

In the specification, the quantum dot (also referred to as semiconductor nanocrystals) may include a group II-VI compound, a group III-V compound, a group IV-VI compound, a group IV element or compound, a group compound, a group compound, a group I-II-IV-VI compound, or a combination thereof.

The group II-VI compound may be selected from a binary compound selected from CdSe, CdTe, ZnS, ZnSe, ZnTe, ZnO, HgS, HgSe, HgTe, MgSe, MgS, and a mixture thereof; a tertiary compound selected from among AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a quaternary compound selected from among HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof. The group II-VI compound may further include a group III metal.

The group III-V compound may be selected from a binary compound selected from GaN, GaP, GaAs, GaSb, AlN, AlP, AlAs, AlSb, InN, InP, InAs, InSb, and a mixture thereof; a tertiary compound selected from among GaNP, GaNAs, GaNSb, GaPAs, GaPSb, AlNP, AlNAs, AlNSb, AlPAs, AlPSb, InGaP, InNP, InNAs, InNSb, InPAs, InZnP, InPSb, and a mixture thereof; and a quaternary compound selected from among GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, InZnP, and a mixture thereof. The group III-V compound may further include a group II metal (e.g., InZnP).

The group IV-VI compound may be selected from a binary compound selected from among SnS, SnSe, SnTe, PbS, PbSe, PbTe, and a mixture thereof; a tertiary compound selected from SnSeS, SnSeTe, SnSTe, PbSeS, PbSeTe, PbSTe, SnPbS, SnPbSe, SnPbTe, and a mixture thereof; and a quaternary compound selected from SnPbSSe, SnPbSeTe, SnPbSTe, and a mixture thereof.

The group IV element or compound may be selected from a unary compound selected from Si, Ge, and a combination thereof; and a binary compound selected from SiC, SiGe, and a combination thereof.

An example of the group compound includes CuInSe₂, CuInS₂, CuInGaSe, and CuInGaS, and is not limited thereto. Examples of the group I-II-IV-VI compound include CuZnSnSe and CuZnSnS, and are not limited thereto. The group IV element or compound may be selected from a singular element material selected from among Si, Ge, and a mixture thereof, and a binary element compound selected from among SiC, SiGe, and a mixture thereof.

The group compound may be selected from ZnGaS, ZnAlS, ZnInS, ZnGaSe, ZnAlSe, ZnInSe, ZnGaTe, ZnAlTe, ZnInTe, ZnGaO, ZnAlO, ZnInO, HgGaS, HgAlS, HgInS, HgGaSe, HgAlSe, HgInSe, HgGaTe, HgAlTe, HgInTe, MgGaS, MgAlS, MgInS, MgGaSe, MgAlSe, MgInSe, and a combination thereof, but is not limited thereto.

The group I-II-IV-VI compound may be selected from CuZnSnSe and CuZnSnS, but is not limited thereto.

In an embodiment, the quantum dots may not include cadmium. The quantum dots may include semiconductor nanocrystals based on the group III-V compound including indium and phosphorus. The group III-V compound may further include zinc. The quantum dots may include a semiconductor nanocrystal based on the group II-VI compound including a chalcogen (e.g., sulfur, selenium, tellurium, or a combination thereof) and zinc.

Regarding the quantum dot, the above-described binary compound, the ternary compound, and/or the quaternary compound may exist in the particles with uniform concentration, or may exist in the same particles with a concentration distribution partially divided into some states. Further, the color conversion media layer may have a core/shell structure where one quantum dot surrounds another quantum dot. An interface between the core and the shell may have a concentration gradient such that a concentration of an element existing in the shell is gradually reduced nearing the center thereof.

In some embodiments, the quantum dot may have a core-shell structure including a core including the above-described nanocrystal and a shell surrounding the core. The shell of the quantum dot may function as a protective layer for maintaining the semiconductor characteristic by preventing chemical denaturation of the core and/or a charging layer for providing an electrophoretic characteristic to the quantum dot. The shell may be a single layer or a multilayer. An interface between the core and the shell may have a concentration gradient such that a concentration of an element existing in the shell is gradually reduced nearing the center thereof. Examples of the shell of the quantum dot include a metallic or non-metallic oxide, a semiconductor compound, or a combination thereof.

For example, the metallic or non-metallic oxide may be binary compounds such as SiO₂, Al₂O₃, TiO₂, ZnO, MnO, Mn₂O₃, Mn₃O₄, CuO, FeP, Fe₂O₃, Fe₃O₄, CoO, Co₃O₄, and NiO, or ternary compounds such as MgAl₂O₄, CoFe₂O₄, NiFe₂O₄, and CoMn₂O₄, but the invention is not limited thereto.

The semiconductor compound may be selected from CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, and AlSb, and the invention is not limited thereto.

An interface between the core and the shell may have a concentration gradient such that a concentration of an element existing in the shell is gradually reduced nearing the center thereof. The semiconductor nanocrystal may have a structure including one semiconductor nanocrystal core and a multi-layered shell surrounding the semiconductor nanocrystal core. In an embodiment, the multi-layered shell may have two or more layers, for example, two, three, four, five, or more layers. The two adjacent layers of the shell may have a single composition or different compositions. In the multi-layered shell, each layer may have a composition that varies along the radius.

The quantum dots may have a full width at half maximum (FWHM) of a light-emitting wavelength spectrum that is less than about 45 nanometers (nm), e.g., less than about 40 nm, or less than about 30 nm, and the quantum dots may improve color purity or color reproducibility within this range. Further, light emitted through the quantum dots is output in all directions, thereby improving a light viewing angle.

Regarding the quantum dots, a shell material and a core material may have different energy bandgaps from each other. In an embodiment, for example, the energy bandgap of the shell material may be greater than that of the core material. In an alternative embodiment, the energy bandgap of the shell material may be less than that of the core material. The quantum dots may have a multi-layered shell. Regarding the multi-layered shell, the energy bandgap of an outer layer may be greater than the energy bandgap of an inner layer (i.e., a layer that is near the core). Regarding the multi-layered shell, the energy bandgap of the outer layer may be less than the energy bandgap of the inner layer.

The quantum dots may adjust the absorption/emission wavelength by adjusting the composition and the size thereof. The maximum light emitting peak wavelength of the quantum dots may have a wavelength range from ultraviolet to infrared or higher.

The quantum dots may have quantum efficiency of greater than or equal to about 10%, for example, greater than or equal to about 30%, greater than or equal to about 50%, greater than or equal to about 60%, greater than or equal to about 70%, greater than or equal to about 90%, or even about 100%. The quantum dot may have a relatively narrow spectrum. The quantum dots may have a FWHM of emission wavelength spectrum of, for example, less than or equal to about 50 nm, for example less than or equal to about 45 nm, less than or equal to about 40 nm, or less than or equal to about 30 nm.

The quantum dot has a particle size of equal to or greater than about 1 nm and equal to or less than about 100 nm. The particle size refers to a particle diameter or a diameter which is calculated under the assumption it has a spherical shape from a two-dimensional (2D) image obtained from transmission electron microscope analysis. The quantum dots may have a particle size of about 1 nm to about 20 nm, for example, equal to or greater than 2 nm, equal to or greater than 3 nm, or equal to or greater than 4 nm, and equal to or less than 50 nm, equal to or less than 40 nm, equal to or less than 30 nm, equal to or less than 20 nm, equal to or less than 15 nm, or equal to or less than 10 nm. The shapes of the quantum dots are not specifically limited. For example, the shapes of the quantum dots may be a sphere, an ellipsoid, a polyhedron, a pyramid, a multipod, a square, a rectangular parallelepiped, a nanotube, a nanorod, a nanowire, a nanosheet, or a combination thereof, but are not limited thereto.

The quantum dots may be commercially available or may be appropriately synthesized. When quantum dots are colloid-synthesized, the particle sizes may be relatively freely controlled and also uniformly controlled.

The quantum dots may include an organic ligand (e.g., having a hydrophobic residue and/or a hydrophilic residue). The organic ligand residue may be combined to the surface of the quantum dot. The organic ligand may include RCOOH, RNH₂, R₂NH, R₃N, RSH, R₃PO, R₃P, ROH, RCOOR, RPO(OH)₂, RHPOOH, R₂HPOOH, or a combination thereof, and here, R may independently be a C3 to C40 substituted or unsubstituted aliphatic hydrocarbon group such as a C3 to C40 (e.g., C5 to C24) substituted or unsubstituted alkyl group, or a substituted or unsubstituted alkenyl group, a C6 to C40 (e.g., C6 to C20) substituted or unsubstituted aromatic hydrocarbon group such as a C6 to C40 substituted or unsubstituted aryl group, or a combination thereof.

Examples of the organic ligand may include thiol compounds such as methane thiol, ethane thiol, propane thiol, butane thiol, pentane thiol, hexane thiol, octane thiol, dodecane thiol, hexadecane thiol, octadecane thiol, or benzyl thiol; amines such as methane amine, ethane amine, propane amine, butane amine, pentyl amine, hexyl amine, octyl amine, nonylamine, decylamine, dodecyl amine, hexadecyl amine, octadecyl amine, dimethyl amine, diethyl amine, dipropyl amine, tributylamine, or trioctylamine; carboxylic acid compounds such as methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, or benzoic acid; phosphine compounds such as methyl phosphine, ethyl phosphine, propyl phosphine, butyl phosphine, pentyl phosphine, octyl phosphine, dioctyl phosphine, tributyl phosphine, or trioctyl phosphine; phosphine compounds or their oxide compounds such as methyl phosphine oxide, ethyl phosphine oxide, propyl phosphine oxide, butyl phosphine oxide, pentyl phosphine oxide, tributyl phosphine oxide, octyl phosphine oxide, dioctyl phosphine oxide, or trioctyl phosphine oxide; diphenyl phosphine, or a triphenyl phosphine compound or oxide compounds thereof; C5 to C20 alkyl phosphinic acids such as hexyl phosphinic acid, octyl phosphinic acid, dodecane phosphinic acid, tetradecane phosphinic acid, hexadecane phosphinic acid, or octadecane phosphinic acid; and C5 to C20 alkyl phosphonic acids. The quantum dot may include the organic ligand alone or as a mixture of at least one kind. The hydrophobic organic ligand may not include a photopolymerizable residue (e.g., an acrylate or methacrylate).

Referring to FIG. 1, in an embodiment, the color conversion layer is not positioned in a portion that corresponds to the blue light emitting area BLA from among the spaces partitioned by the banks 320. Instead, a transmission layer 330P may be positioned in a portion that corresponds to the blue light emitting area BLA. The transmission layer 330P may include scatterers. The scatterers may be selected from among at least one selected from SiO₂, BaSO₄, Al₂O₃, ZnO, ZrO₂, and TiO₂. The transmission layer 330P may include a polymer resin and scatterers included in the polymer resin. For example, the transmission layer 330P may include TiO₂, but is not limited thereto. The transmission layer 330P may transmit light input from the display panel.

Referring to FIG. 1, the green color conversion layer 330G and the red color conversion layer 330R may be stacked one on another and positioned in the white light emitting area WLA. In such an embodiment where the green color conversion layer 330G and the red color conversion layer 330R are positioned in the white light emitting area WLA, white light may be emitted according to a ratio thereof.

In an embodiment of the invention, the color converting panel includes red, green, blue, and white light emitting areas. The color converting panel may convert the incident blue light or white light, and may emit light. In such an embodiment, a high-luminance image may mainly use the white light emitting area to display the image, and hence, light efficiency of the display device to which the color converting panel is applied may be increased.

FIG. 1 shows an embodiment having a configuration in which the white light emitting area WLA includes no color filter. Alternatively, the color filter 230 may be positioned in the white light emitting area WLA.

FIG. 2 shows a cross-sectional view of an alternative embodiment of a color converting panel shown in FIG. 1. Referring to FIG. 2, an alternative embodiment of the color converting panel corresponds to the embodiment described above with reference to FIG. 1 except that the color converting panel further includes a reflective color filter 230W positioned in the white light emitting area WLA. Any repetitive detailed description of the same constituent elements as those described above will be omitted. Referring to FIG. 2, an embodiment of the color converting panel includes a reflective color filter 230W positioned in the white light emitting area WLA. The reflective color filter 230W may be a gray color filter but is not limited thereto. The reflective color filter 230W may reduce a reflection ratio of the color converting panel.

FIG. 1 shows an embodiment having a configuration in which a light blocking member 220 is positioned between the respective color filters 230. In an alternative embodiment, a color filter stacked body A may be positioned between the respective color filters 230 instead of the light blocking member 220.

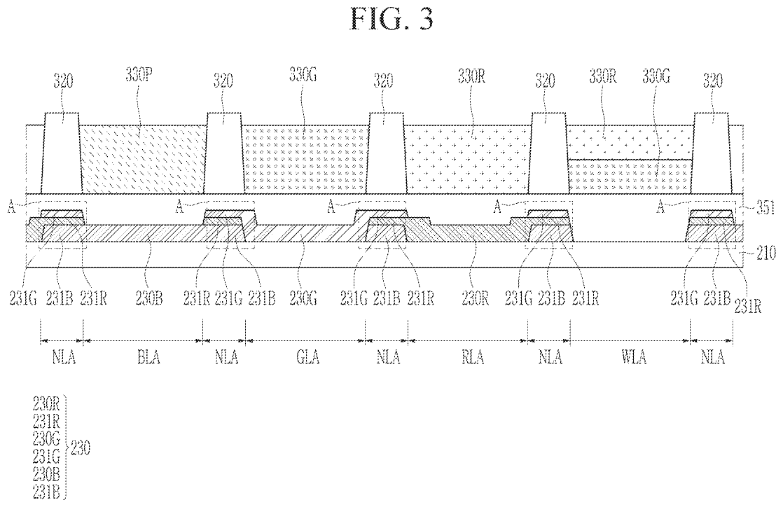

FIG. 3 shows a cross-sectional view of another alternative embodiment of a color converting panel shown in FIG. 1. Referring to FIG. 3, an alternative embodiment of the color converting panel corresponds to the embodiment described above with reference to FIG. 1 except that the color filter stacked body A is positioned between the respective color filters 230. Any repetitive detailed description of the same constituent elements as those described above will be omitted.

Referring to FIG. 3, in an embodiment, a blue dummy color filter 231R is positioned in a same layer as the blue color filter 230B. The blue color filter 230B may be positioned in the blue light emitting area BLA, and the blue dummy color filter 231R may be positioned in the non-light emitting area NLA overlapping the bank 320. FIG. 1 shows that the blue color filter 230B and a blue dummy color filter 231B are separated from each other in a cross-section, but the blue color filter 230B and a blue dummy color filter 231B may be connected to each other. That is, the blue color filters may be positioned in the entire region excluding the green light emitting area GLA, the red light emitting area RLA, and the white light emitting area WLA. From among the blue color filters, the blue color filter positioned in the blue light emitting area BLA is the blue color filter 230B, and the blue color filter positioned in the non-light emitting area NLA is the blue dummy color filter 231B.

A red color filter 230R and a red dummy color filter 231R are positioned on the blue color filter 230B and the blue dummy color filter 231B. The color filter may be positioned in the entire region excluding the green light emitting area GLA, the blue light emitting area BLA, and the white light emitting area WLA. From among the red color filters, the red color filter positioned in the red light emitting area RLA is the red color filter 230R, and the red color filter positioned in the non-light emitting area NLA is the red dummy color filter 231R. Referring to FIG. 3, respective edges of the red color filter 230R are in the non-light emitting area NLA overlapping the bank 320, that is, the red dummy color filter 231R.

A green color filter 230G and a green dummy color filter 231G are positioned on the blue color filter 230B and the blue dummy color filter 231B, and the red color filter 230R and the red dummy color filter 231R

The green color filter may be positioned in the entire region excluding the blue light emitting area BLA, the red light emitting area RLA, and the white light emitting area WLA. From among the green color filters, the green color filter positioned in the green light emitting area GLA is the green color filter 230G, and the green color filter positioned in the non-light emitting area NLA is the green dummy color filter 231G. Referring to FIG. 3, respective edges of the green color filter 230G are in the non-light emitting area NLA overlapping the bank 320, that is, the green dummy color filter 231G.

Referring to FIG. 3, the blue dummy color filter 231B, the red dummy color filter 231R, and the green dummy color filter 231G overlap each other in the region overlapping the bank 320. The blue dummy color filter 231B, the red dummy color filter 231R, and the green dummy color filter 231G overlap each other to define or form a color filter stacked body A. The color filter stacked body A may function as a light blocking member. That is, the color filter stacked body A may block light in the non-light emitting area NLA.

In such an embodiment, the blue dummy color filter 231B may be positioned closer to the first substrate 210 than the red dummy color filter 231R and the green dummy color filter 231G are. A direction in which a user views images goes toward the first substrate 210, and the blue dummy color filter 231B may be positioned on a side on which the images are seen. This is because the blue color has the lowest reflection ratio for the entire light and most efficiently blocks light compared to the green or red color.

Referring to FIG. 1 to FIG. 3, the white light emitting area WLA shows a structure in which the green color conversion layer 330G and the red color conversion layer 330R are sequentially stacked, and the stacked structure in the white light emitting area WLA may be variously modified. Various embodiments will now be described.

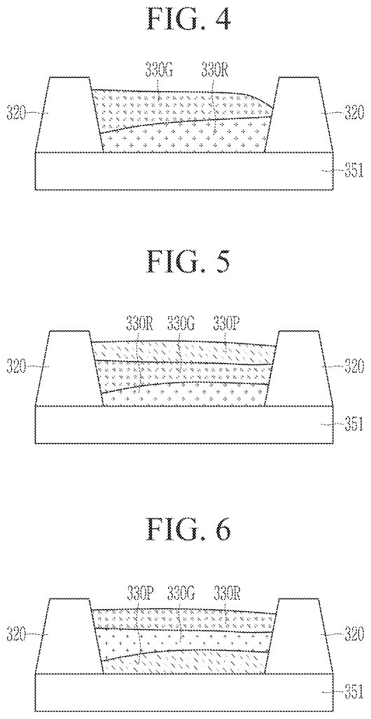

FIG. 4 to FIG. 9 are enlarged views showing embodiments of with the circled portion B in FIG. 1. Referring to FIG. 4, in an embodiment, the white light emitting area WLA of the color converting panel may have a structure in which the red color conversion layer 330R is stacked on the refractive layer 351 and the green color conversion layer 330G is then stacked on the red color conversion layer 330R. In such an embodiment, the red color conversion layer 330R may be positioned closer to the first substrate 210 than the green color conversion layer 330G is.

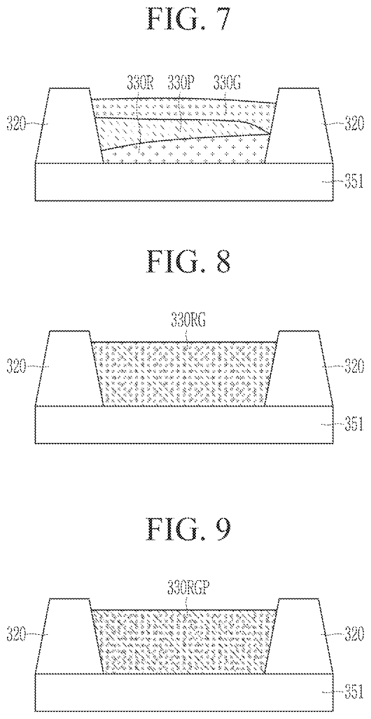

Referring to FIG. 5, in an alternative embodiment, the white light emitting area WLA of the color converting panel may include the red color conversion layer 330R, the green color conversion layer 330G, and the transmission layer 330P. FIG. 5 shows an embodiment where the transmission layer 330P is positioned the farthest from the first substrate 210, and the position of the transmission layer 330P may be variously modified. In another alternative embodiment, as shown in FIG. 6, the transmission layer 330P may be positioned closer to the first substrate 210 than the red color conversion layer 330R and the green color conversion layer 330G are. In another alternative embodiment, as shown in FIG. 7, the transmission layer 330P may be positioned between the red color conversion layer 330R and the green color conversion layer 330G.

Referring to FIG. 8, a mixed color conversion layer 330RG on which the red color conversion layer 330R and the green color conversion layer 330G are mixed may be positioned in the white light emitting area WLA of the color converting panel. The mixed color conversion layer 330RG may be formed by concurrently injecting the red color conversion layer 330R and the green color conversion layer 330G according to an inkjet method. The mixed color conversion layer 330RG may include a quantum dot for color-converting incident light into red light and a quantum dot for color-converting incident light into green light.

Referring to FIG. 9, a mixed color conversion layer 330RGP on which the red color conversion layer 330R, the green color conversion layer 330G, and the transmission layer 330P are mixed may be positioned in the white light emitting area WLA of the color converting panel. The mixed color conversion layer 330RGP may be formed by concurrently injecting the red color conversion layer 330R, the green color conversion layer 330G, and the transmission layer 330P according to the inkjet method. The mixed color conversion layer 330RGP may include a quantum dot for color-converting incident light into red light, a quantum dot for color-converting incident light into green light, and scatterers.

Referring to FIG. 4 to FIG. 9, in an embodiment, the color conversion layer 330R and the 330G and the transmission layer 330P may be formed by the inkjet method. In embodiments, as described above, the color conversion layer but the transmission layer 330P may be positioned in the blue light emitting area BLA, but not being limited thereto. Alternatively, the blue color conversion layer 330B may be positioned in the blue light emitting area BLA.

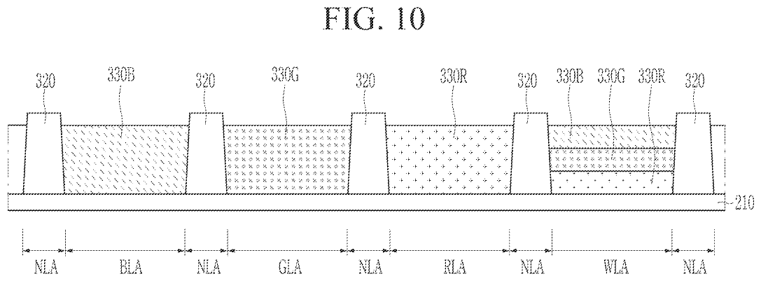

FIG. 10 shows a cross-sectional view of another alternative embodiment of a color converting panel shown in FIG. 1. Referring to FIG. 10, an alternative embodiment of the color converting panel corresponds to the embodiment described above with reference to FIG. 1 except that the blue color conversion layer 330B is positioned in the blue light emitting area BLA, the red color conversion layer 330R, the green color conversion layer 330G, and the blue color conversion layer 330B are positioned in the white light emitting area WLA, and the color filter 230 is not included. Any repetitive detailed description of the same constituent elements as those described above will be omitted. Referring to FIG. 10, in an embodiment of the color converting panel, not the transmission layer but the blue color conversion layer 330B is positioned in the blue light emitting area BLA. The blue color conversion layer 330B may include a quantum dot, and may convert incident light into blue light.

In an embodiment, as shown in FIG. 10, the white light emitting area WLA may have a structure in which the red color conversion layer 330R, the green color conversion layer 330G, and the blue color conversion layer 330B are sequentially stacked. In such an embodiment, white light may emit in the white light emitting area WLA. The embodiment of FIG. 10 shows a stacked configuration in order of the red color conversion layer 330R, the green color conversion layer 330G, and the blue color conversion layer 330B, but the stacked order is not limited thereto and may be variously modified.

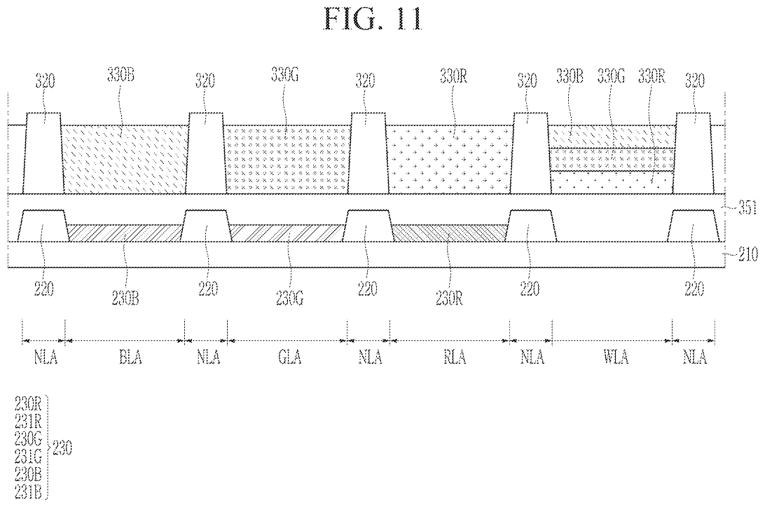

The color converting panel according to an embodiment of FIG. 10 has a configuration including no color filter, but not being limited thereto. Alternatively, the color converting panel may include a color filter, as shown in FIG. 11.

FIG. 11 shows a cross-sectional view of another alternative embodiment of a color converting panel shown in FIG. 10. In an alternative embodiment, color filters 230 including a blue color filter 230B, a red color filter 230R, and a green color filter 230G may be positioned on the first substrate 210. The respective color filters are positioned corresponding to the respective light emitting areas. That is, the blue color filter 230B may be positioned in the blue light emitting area BLA, the red color filter 230R may be positioned in the red light emitting area RLA, and the green color filter 230G may be positioned in the green light emitting area GLA. A light blocking member 220 may be positioned between the respective color filters 230. Although not shown in FIG. 11, a reflective color filter may be positioned in the white light emitting area WLA.

In an alternative embodiment, not the light blocking member 220 but the color filter stacked body A may be positioned.

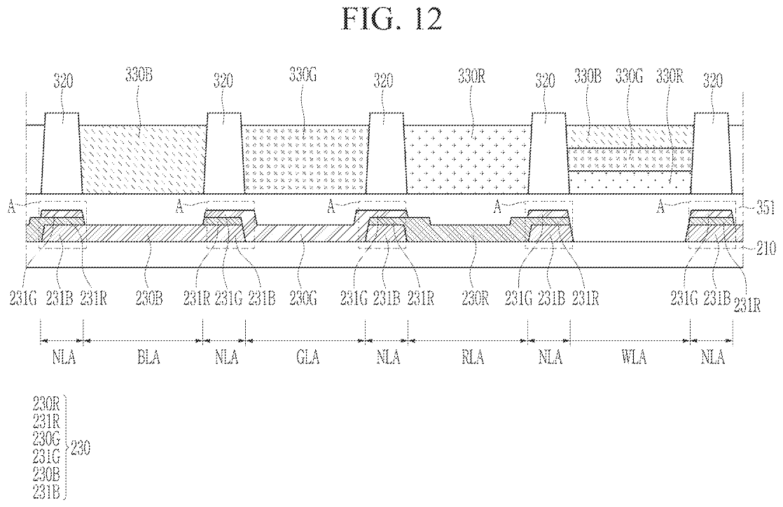

FIG. 12 shows a cross-sectional view of another alternative embodiment of a color converting panel shown in FIG. 10, and the color converting panel according to the embodiment corresponds to the embodiment described with reference to FIG. 10 except that the color filter stacked body A is positioned between the respective color filters 230. Any repetitive detailed description of the same constituent elements as those described above will be omitted. In such an embodiment, the color filter stacked body A is substantially the same as that described above with reference to FIG. 3 so any repetitive detailed description thereof will be omitted.

FIG. 10 shows an embodiment in which the red color conversion layer 330R, the green color conversion layer 330G, and the blue color conversion layer 330B are sequentially stacked or arranged in a vertical direction in the white light emitting area WLA, but not being limited thereto. Alternative, the red color conversion layer 330R, the green color conversion layer 330G, and the blue color conversion layer 330B may be positioned or arranged in a horizontal direction within partitions in the white light emitting area WLA.

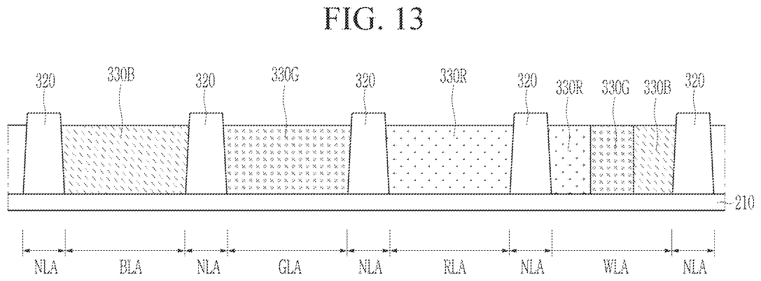

FIG. 13 shows a cross-sectional view of another alternative embodiment of a color converting panel shown in FIG. 10. Referring to FIG. 13, in an embodiment of the color converting panel, the red color conversion layer 330R, the green color conversion layer 330G, and the blue color conversion layer 330B are positioned within the partitions in the white light emitting area WLA. That is, the red color conversion layer 330R, the green color conversion layer 330G, and the blue color conversion layer 330B may not overlap each other in a thickness direction of the first substrate 210 and may be positioned in parallel to each other in a direction that is perpendicular to the thickness direction of the first substrate 210. In such an embodiment, as in the embodiment of FIG. 10, white light is emitted in the white light emitting area WLA.

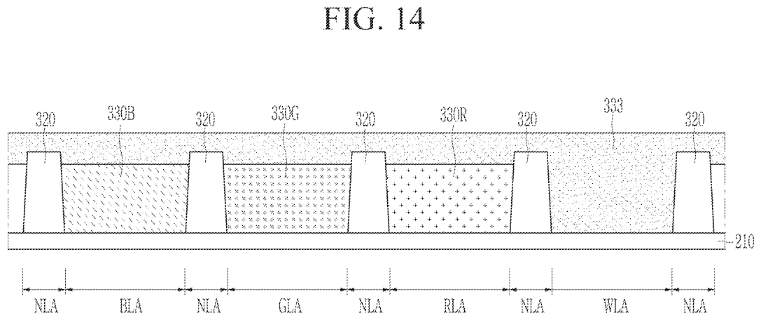

FIG. 14 shows a cross-sectional view of another alternative embodiment of a color converting panel shown in FIG. 10. Referring to FIG. 14, an alternative embodiment of the color converting panel corresponds to the embodiment described above with reference to FIG. 10 except that the scatterer layer 333 is positioned in the white light emitting area WLA. Any repetitive detailed description of the same constituent elements as those described above will be omitted. Referring to FIG. 14, in an embodiment of the color converting panel, the scatterer layer 333 may overlap the white light emitting area WLA, the green light emitting area GLA, the red light emitting area RLA, and the blue light emitting area BLA. The scatterer layer 333 may include scatterers. The scatterers may be at least one selected from SiO₂, BaSO₄, Al₂O₃, ZnO, ZrO₂, and TiO₂. In such an embodiment where the scatterer layer 333 is positioned in the entire region of the color converting panel, the respective red color conversion layer 330R, the green color conversion layer 330G, and the blue color conversion layer 330B may include no scatterers. In such an embodiment where the color conversion layer includes no scatterers, scattering may occur in the scatterer layer 333. In an embodiment, the respective color conversion layers may include scatterers.

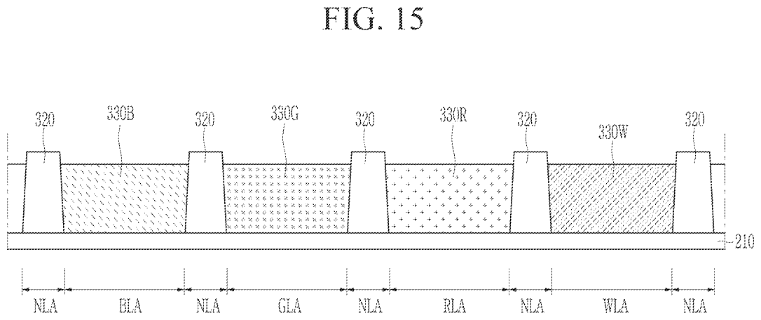

FIG. 15 shows a cross-sectional view of another alternative embodiment of a color converting panel shown in FIG. 10. Referring to FIG. 15, an alternative embodiment of the color converting panel corresponds to the embodiment described with reference to FIG. 10 except that the white color conversion layer 330W is positioned in the white light emitting area WLA. Any repetitive detailed description of the same constituent elements as those described above will be omitted. The white color conversion layer 330W may color-convert incident light into white light.

In an embodiment described above with reference to FIG. 10 to FIG. 15, the respective color conversion layers may be formed by performing exposure and etching by using a photoresist, but not being limited thereto. In an embodiment where the respective color conversion layers are formed by using a photoresist, the color conversion layer positioned in the white light emitting area may be formed by using a halftone mask.

An embodiment of the color converting panel may be combined with a display panel to configure the display device. The display panel may emit white light or may emit blue light. In some embodiments, the display panel may have a structure in which emission layers for emitting various colors are stacked. In an embodiment, for example, the display panel may have a stacked structure of emission layers for emitting blue light and yellow light, or emission layers for emitting blue light, green light, and red light.

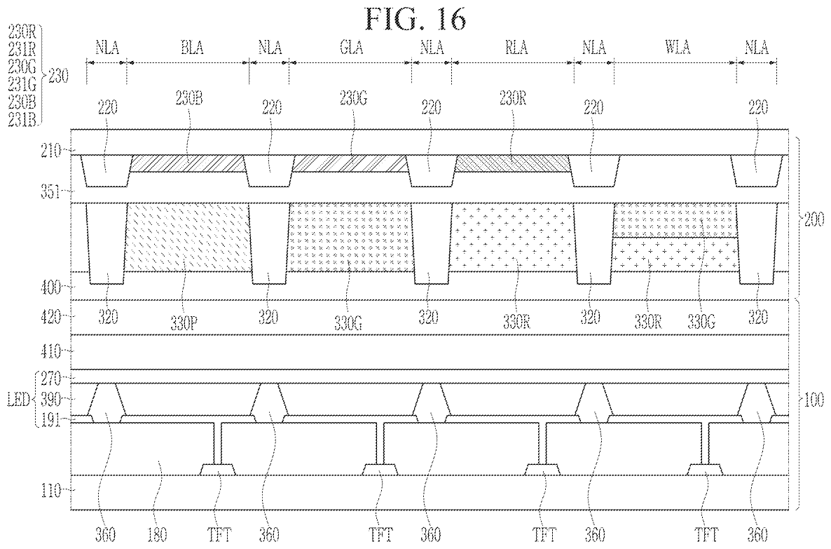

A display device including a color converting panel according to an embodiment will now be described with reference to FIG. 16.

FIG. 16 shows a cross-sectional view of a display device according to an embodiment. Referring to FIG. 16, an embodiment of the display device includes a display panel 100 and a color converting panel 200. In such an embodiment, the color converting panel 200 corresponds to those described with reference to FIG. 1 to FIG. 15 so any repetitive detailed description thereof will be omitted. FIG. 16 shows an embodiment where the color converting panel 200 in the display device has the structure of the color converting panel shown in FIG. 1, this is however an example, and the color converting panel 200 of FIG. 16 may be variously modified as described above withe reference to FIG. 2 to FIG. 15.

The display panel 100 includes a second substrate 110 and a plurality of transistors TFT and insulating layers 180 positioned on the second substrate 110. A first electrode 191 and a partition wall 360 are positioned on the insulating layer 180, and the first electrode 191 is positioned in an opening of the partition wall 360 and is connected to the transistor TFT. Although not shown in detail, the transistor TFT may include a semiconductor layer, a source electrode and a drain electrode connected to the semiconductor layer, and a gate electrode insulated from the semiconductor layer. A second electrode 270 is positioned on the partition wall 360, and a light-emitting device layer 390 is positioned between the first electrode 191 and the second electrode 270. The first electrode 191, the second electrode 270, and the light-emitting device layer 390 will be configured and referred to as a light-emitting device LED. A plurality of light-emitting devices LED may emit light of different colors from each other or may emit light of a same color as each other. In an embodiment, for example, the light-emitting devices LED may emit red, green, and blue light. Alternatively, the light-emitting device LED may emit white light. The light-emitting devices LED may have a structure in which the light-emitting devices for emitting light of different colors are stacked. In an embodiment, for example, the light-emitting device LED may have a structure in which an emission layer for emitting blue light and an emission layer for emitting yellow light are stacked. In an alternative embodiment, emission layers for emitting blue light, green light, and red light may be stacked. The partition wall 360 may include a black material and may prevent mixture of colors between the neighboring light-emitting devices LED.

An encapsulation layer 410 may be positioned on the light-emitting device LED of the display panel 100. The encapsulation layer 410 may have a multi-layered structure in which an organic film and an inorganic film are alternately stacked. From among the multi-layered encapsulation layer 410, a layer disposed the farthest from the first substrate 210 may include SiON.

A buffer layer 420 may be positioned between the encapsulation layer 410 and the first insulating layer 400. The buffer layer 420 may combine the display panel 100 and the color converting panel 200 to each other. The buffer layer 420 may include an organic material. A refractive index of the buffer layer 420 may be in a range of about 1.6 to about 1.7. The refractive index is in the range may have improve extracting efficiency of light emitted by the display panel 100.

Referring to FIG. 16, a first insulating layer 400 positioned on an upper side of the color converting panel 200 may be included. The first insulating layer 400 caps the color conversion layer. The first insulating layer 400 may include SiON. A thickness of the first insulating layer 400 may be in a range of about 3500 angstroms (Å) to about 4500 Å. The refractive index of the first insulating layer 400 may be in a range of about 1.4 to about 1.6. The first insulating layer 400 may include an inorganic material.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A color converting panel comprising:
a substrate;
a plurality of banks disposed on the substrate, wherein the banks partition a red light emitting area, a green light emitting area, a blue light emitting area, and a white light emitting area;
a red color conversion layer disposed in the red light emitting area;
a green color conversion layer disposed in the green light emitting area; and
a green color conversion layer and a red color conversion layer disposed in the white light emitting area.

2. The color converting panel of claim 1, wherein
the green color conversion layer and the red color conversion layer in the white light emitting area are stacked one on another.

3. The color converting panel of claim 1, wherein
the green color conversion layer and the red color conversion layer in the white light emitting area are mixed with each other to define a single layer.

4. The color converting panel of claim 1, further comprising
a transmission layer disposed in the blue light emitting area and the white light emitting area.

5. The color converting panel of claim 4, wherein
the green color conversion layer, the red color conversion layer, and the transmission layer in the white light emitting area are stacked one on another.

6. The color converting panel of claim 4, wherein
the green color conversion layer, the red color conversion layer, and the transmission layer in the white light emitting area are mixed with each other to define a single layer in the white light emitting area.

7. The color converting panel of claim 1, further comprising:
a blue color conversion layer disposed in the blue light emitting area and the white light emitting area.

8. The color converting panel of claim 7, wherein
the green color conversion layer, the red color conversion layer and the blue color conversion layer in the white light emitting area are stacked one on another.

9. The color converting panel of claim 7, wherein
the green color conversion layer, the red color conversion layer, and the blue color conversion layer in the white light emitting area are sequentially arranged in a direction perpendicular to a thickness direction of the substrate.

10. The color converting panel of claim 1, further comprising:
a red color filter disposed on the substrate and overlapping the red light emitting area;
a green color filter disposed on the substrate and overlapping the green light emitting area; and
a blue color filter disposed on the substrate and overlapping the blue light emitting area.

11. The color converting panel of claim 10, further comprising
a reflective color filter disposed on the substrate and overlapping the white light emitting area.

12. A color converting panel comprising:
a substrate;
a plurality of banks disposed on the substrate, wherein the banks partition a red light emitting area, a green light emitting area, a blue light emitting area, and a white light emitting area;
a red color conversion layer disposed in the red light emitting area;
a green color conversion layer disposed in the green light emitting area;
a blue color conversion layer disposed in the blue light emitting area; and
a scatterer layer disposed in the white light emitting area,
wherein the scatterer layer is disposed to overlap the red color conversion layer, the green color conversion layer, and the blue color conversion layer.

13. A color converting panel comprising:
a substrate;
a plurality of banks disposed on the substrate, where the banks partition a red light emitting area, a green light emitting area, a blue light emitting area, and a white light emitting area;
a red color conversion layer disposed in the red light emitting area;
a green color conversion layer disposed in the green light emitting area;
a blue color conversion layer disposed in the blue light emitting area; and
a white color conversion layer disposed in the white light emitting area.

14. A display device comprising:
a color converting panel; and
a display panel overlapping the color converting panel,
wherein the display panel includes:
a second substrate:
a plurality of partition walls disposed on the second substrate: and
an emission layer disposed between the partition walls, and
the color converting panel includes:
a first substrate:
a plurality of banks disposed on the first substrate, where the banks partition a red light emitting area, a green light emitting area, a blue light emitting area, and a white light emitting area:
a red color conversion layer disposed in the red light emitting area:
a green color conversion layer disposed in the green light emitting area: and
a green color conversion layer and a red color conversion layer disposed in the white light emitting area.

15. The display device of claim 14, wherein
the emission layer includes at least one emission layer, and
the display panel emits blue light or white light.

16. The display device of claim 14, wherein
the green color conversion layer and the red color conversion layer in the white light emitting area are stacked one on another, or
the green color conversion layer and the red color conversion layer in the white light emitting area are mixed with each other to define a single layer.

17. The display device of claim 14, further comprising
a transmission layer disposed in the blue light emitting area and the white light emitting area.

18. The display device of claim 17, wherein
the green color conversion layer, the red color conversion layer, and the transmission layer in the white light emitting area are stacked one on another, or
the green color conversion layer, the red color conversion layer, and the transmission layer in the white light emitting area are mixed with each other to define a single layer.

19. The display device of claim 14, further comprising
a blue color conversion layer disposed in the blue light emitting area and the white light emitting area.

20. The display device of claim 19, wherein
the green color conversion layer, the red color conversion layer, and the blue color conversion layer in the white light emitting area are stacked one on another, or
the green color conversion layer, the red color conversion layer, and the blue color conversion layer in the white light emitting area are sequentially arranged in a direction perpendicular to a thickness direction of the first substrate.
